(19) United States
(12) Patent Application Publication
(10) Pub. No.: US 2026/0259259 A1
(43) Pub. Date: Sep. 3, 2026

(54) COMMON DEBUG NETWORK FOR CHIPLET AND MULTI-CHIPSET ARCHITECTURES

(71) Applicant: QUALCOMM Incorporated, San Diego, CA (US)

(72) Inventors: Manas Ranjan MOHANTA, Chennai (IN); Sakthikumaran SAMIAPPA, Chennai (IN)

(21) Appl. No.: 19/067,575

(22) Filed: Feb. 28, 2025

(51) Int. Cl. G01R 31/317; G01R 31/3185; G01R 31/319

(52) U.S. Cl. CPC G01R 31/31705; G01R 31/318533; G01R 31/31926

(57) ABSTRACT

A common debug network is provided for a chiplet-based or a chipset-based system. In the systems, a primary die includes an external debugger interface for coupling to an external debugger. The external debugger may debug a target circuit in the primary die through the external debugger interface. Alternatively, the external debugger may debug a target circuit in a secondary die through a common debug network coupled between the primary die and the secondary die.

### TECHNICAL FIELD

The present application relates generally to integrated circuit debugging, and more particularly to an improved common debug network for chiplet and multi-chipset architectures.

### BACKGROUND

A computing system typically includes various sub-systems such as central processing units (CPUs), a graphics processing unit (GPU), memory such as dynamic random-access memory (DRAM), static random-access memory (SRAM), and flash storage, input/output interfaces such a universal serial bus (USB), WiFi, and Bluetooth, and various other sub-systems such as a digital signal processor (DSP) and a power management unit (PMU). Traditionally such a computing system was fairly large and occupied a motherboard but as semiconductor processing has advanced a computing system may now be integrated into a single system-on-a-chip (SoC) integrated circuit. But the complexity and expense of SoCs have led to the development of alternative architectures such a chiplet-based system. In a chiplet-based system, the SoC is divided into smaller modular integrated circuits. Alternatively, an SoC may be developed as a multi-chipset system that include multiple chips (integrated circuit dies) that do not work together in a modular fashion as do chiplets. The dies in a chipset-based system communicate with each other through die-to-die interfaces such as a Peripheral Component Interconnect Express (PCI Express) interface.

Regardless of whether a chiplet-based or a chipset-based architecture is used, the resulting system presents complications with respect to debugging such as through a Joint Test Action Group (JTAG) interface or a Serial Wire Debug (SWD) interface. A JTAG interface requires a minimum of four integrated circuit terminals or pins. Similarly, a SWD interface uses two integrated circuit terminals. A debugger such as an automated test equipment (ATE) can be used to debug a chipset or a chiplet using the JTAG or SWD protocol and the hardware module in the chipset that supports the JTAG or SWD interface to the debugger through a USB interface is denoted as an Embedded USB Debug (EUD). Each chiplet die or chipset die must be accessible for the debugging. A chiplet package that supports a JTAG-based debugging would thus need four integrated circuit terminals or pins for each chiplet. A separate external debugger must then be coupled to the corresponding chiplet through its interface. A similar complication exists for a chipset-based system. The resulting number of pins and the need for individual debuggers makes the debugging of chiplet-based or multi-chipset-based systems costly and complicated.

### SUMMARY

In accordance with an aspect of the disclosure, a system is provided that includes: a first chiplet die including: a first debugging interface for coupling to an external debugger; a first multiplexer coupled to the first debugging interface; a first target circuit; a first debug subsystem configured to debug the first target circuit with first debugging signals coupled through the first multiplexer from the first debugging interface; a first set of terminals from a first inter-chiplet interface, wherein the first set of terminals is coupled to the first multiplexer; and a second chiplet die including: a second set of terminals from a second inter-chiplet interface, wherein the second set of terminals is coupled to the first set of terminals; a second multiplexer coupled to the second set of terminals; a second target circuit; and a second debug subsystem configured to debug the second target circuit with second debugging signals coupled through the second multiplexer from the second set of terminals.

In accordance with another aspect of the disclosure, a method of debugging is provided that includes: coupling a plurality of first debugging signals from an external debugger through a first multiplexer in a first die to a first debug subsystem in the first die; debugging a first target circuit in the first die using the plurality of first debugging signals and the first debug subsystem; coupling a plurality of second debugging signals from the external debugger through the first multiplexer and through a second multiplexer in a second die to a second debug subsystem in the second die; and debugging a second target circuit in the second die using the plurality of second debugging signals and the second debug subsystem.

Finally, in accordance with yet another aspect of the disclosure, a system is provided that includes: a first chipset die including: a first debugging interface for coupling to an external debugger; a first multiplexer coupled to the first debugging interface; a first target circuit; a first debug subsystem configured to debug the first target circuit with first debugging signals coupled through the first multiplexer from the first debugging interface; a first set of terminals from a first die-to-die interface, wherein the first set of terminals is coupled to the first multiplexer; and a second chiplet die including: a second set of terminals from a second die-to-die interface, wherein the second set of terminals is coupled to the first set of terminals; a second multiplexer coupled to the second set of terminals; a second target circuit; and a second debug subsystem configured to debug the second target circuit with second debugging signals coupled through the second multiplexer from the second set of terminals.

These and other advantageous features may be better appreciated through the following detailed description.

### BRIEF DESCRIPTION OF THE DRAWINGS

FIG. 1 illustrates a chiplet-based system including a primary chiplet die having an external debugging interface for debugging the chiplet-based system in accordance with an aspect of the disclosure.

FIG. 2 is a more detailed view of the primary chiplet die and a secondary chiplet die in the chiplet-based system of FIG. 1 in accordance with an aspect of the disclosure.

FIG. 3 illustrates a chipset-based system including a primary die having an external debugging interface for debugging the chipset-based system in accordance with an aspect of the disclosure.

FIG. 4 illustrates a chipset-based system including a primary die having an external debugging interface for debugging the chipset-based system in accordance with an aspect of the disclosure.

FIG. 5 is a more detailed view of the primary die and a secondary die in the chipset-based system of FIG. 4 in accordance with an aspect of the disclosure.

FIG. 6 illustrates an example computer-based system for implementing aspects of the debugging systems disclosed herein in accordance with an aspect of the disclosure.

FIG. 7 is a flowchart for an example method of debugging in accordance with an aspect of the disclosure.

Implementations of the present disclosure and their advantages are best understood by referring to the detailed description that follows. It should be appreciated that like reference numerals are used to identify like elements illustrated in one or more of the figures.

### DETAILED DESCRIPTION

An improved debugging architecture is provided for chiplet-based and multi-chipset-based systems. A host die in the debugging architecture includes an interface to couple to an external debugger. One particularly advantageous external debugger is an Embedded USB Debug (EUD) debugger that supports both Serial Wire Debug (SWD) and Joint Test Action Group (JTAG) protocols, but it will be appreciated that any suitable debugger such as a SWD or JTAG external debugger may be used herein. As compared to JTAG, the SWD protocol requires only two wires/terminals and supports a higher clock frequency. The following discussion will thus be directed to debugging architectures in which the SWD protocol is used but JTAG is also supported by the debugging architecture disclosed herein.

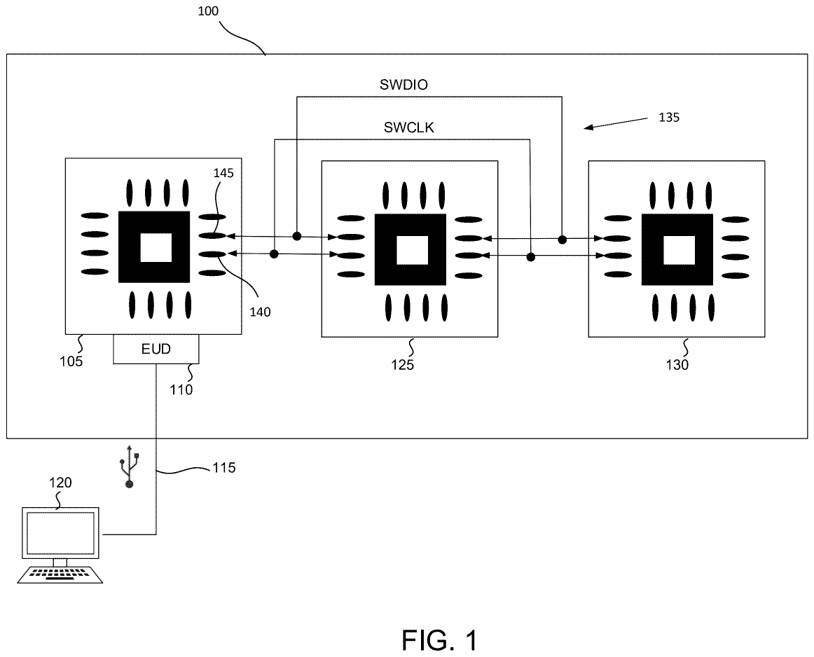

Regardless of whether the debugging architecture is implemented in a chiplet-based or chipset-based system, the system includes a host die. Some example chiplet-based systems with a host die and one or more secondary dies will now be discussed followed by a discussion of some example chipset-based systems. In a chiplet-based system, the host die is a host chiplet die. An example chiplet-based system 100 is shown in FIG. 1 that includes a host die 105, and two secondary dies 125 and 130. An external EUD debugger 120 couples through a USB interface 115 to an EUD debug subsystem 110 in the host die 105. As will be explained further herein, the EUD debug subsystem 110 in the host die 105 is modified so that it not only responds to debugging signals directed to the host die 105 but will also network debugging signals from the external debugger 120 to secondary dies 125 and 130. As will further be explained herein, each of the secondary dies 125 and 130 includes a debug subsystem (not illustrated in FIG. 1 but assumed to be an EUD debug subsystem in some implementations) that networks with the external debugger 120 through the host die's EUD debug subsystem 110. For example, as known in the integrated circuit arts, each of the dies 105, 125, and 130 includes a set of general-purpose input/output (GPIO) terminals that may be re-purposed for debugging as disclosed herein. If SWD is used for the debugging, one GPIO terminal for each die is dedicated during a debugging session to the SWD input/output (SWDIO) signal. For example, the host die 105 includes a GPIO terminal 140 for the SWDIO signal. Similarly, another GPIO terminal for each die is dedicated during a debugging session to the SWD clock signal (SWDCLK). For example, the host die 105 includes a GPIO terminal 145 for the SWDCLK signal. Each die thus has a set of two GPIO terminals that may be reserved for the die-to-die SWD debugging signal transmission. If JTAG is used for the debugging, each die would have a minimum of four of its GPIO terminals used or reserved respectively for the TDIO, TDO, TMS, and TCK signals. A fifth terminal for the TRST signal is optional. As compared to JTAG, the SWD protocol advantageously supports a star bus networking such that the two GPIO terminals for each of the die may be coupled through a star bus network 135. In contrast, JTAG uses a daisy-chain topology for the networking of the four JTAG signals. A JTAG network is thus not shown in FIG. 1 but would be included if the debugging proceeds under the JTAG protocol instead of SWD. Regardless of whether the JTAG or SWD protocol is used, note that a single external debugger such as the debugger 120 may debug the secondary dies 125 and 130 through its interface to the host die 105. This is quite advantageous in reducing the debugging complexity. For example, a conventional JTAG debugging of the secondary dies 125 and 130 would require an external debugger for each die as coupled through four corresponding JTAG terminals, which makes the debugging excessively complicated and costly. But in system 100, only one external debugger 120 is used with just one corresponding set of terminals. In alternative implementations, the external debugger 120 may use a system trace debugging protocol or a universal asynchronous receiver/transmitter (UART) debugging protocol instead of the SWD or JTAG protocols.

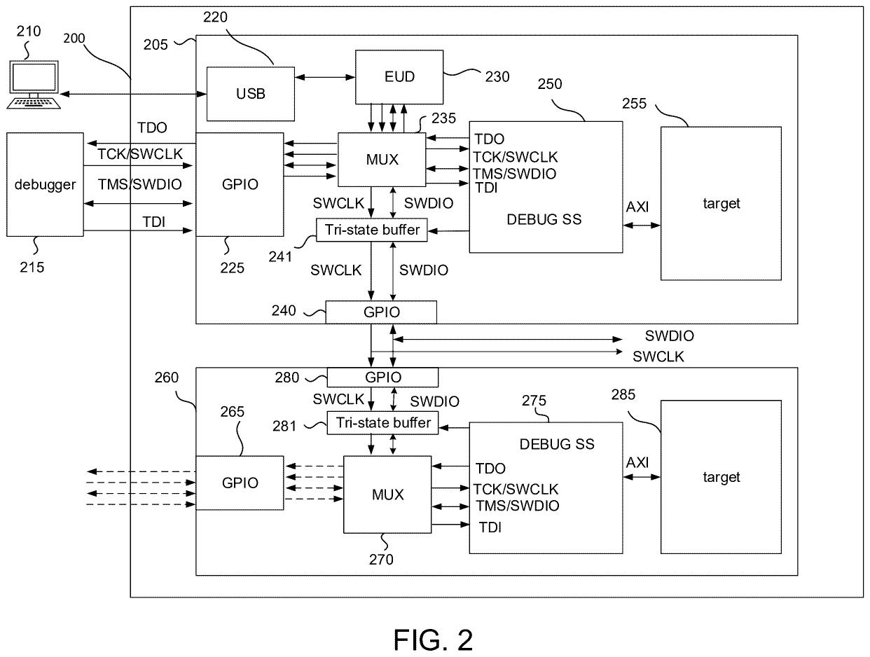

An example chiplet-based system 200 is shown in more detail in FIG. 2. System 200 includes a host die 205 and one or more secondary dies (for illustration clarity, only a single secondary die 260 is shown in FIG. 2). An external EUD debugger 210 couples through a USB interface 220 to an EUD controller 230 in the host die 205. Should the SWD protocol be used by the debugger 210, the EUD controller 230 interfaces through a multiplexer 235 with the SWDIO and SWDCLK signals. Alternatively, the debugger 210 may use the JTAG protocol so that JTAG signaling proceeds between the EUD controller 230 and the multiplexer 235 with the JTAG signals TDI, TDO, TMS, and TCK signals. If the debugging signals are directed to the debugging of the host die 205, the debugging signals couple through the multiplexer 235 to a debug subsystem 250 for the debugging of a target circuit 255 (for example, a processor or an embedded memory) in the host die 205. The clock signals TCK and SWCLK are unidirectional and may propagate on the same path from EUD controller 230 through the multiplexer 235 to the debug subsystem 250. Similarly, the JTAG signals TDI and TDO are unidirectional. The TDI signal propagates from the EUD controller 230 through the multiplexer 235 to the debug subsystem 250. Conversely, the TDO signal propagates from the debug subsystem 250 through the multiplexer 235 to the EUD controller 230.

In lieu of using the EUD debugger 210, an external debugger 215 such as a SWD or a JTAG debugger may couple its JTAG or SWD debugging signals through GPIO terminals 225 to the multiplexer 235 and from the multiplexer 235 to the debug subsystem 250 for the debugging of the target circuit 255. Regardless of whether the EUD debugger 210 or the debugger 215 is used, the debugging target circuit may instead be a secondary die such as the secondary die 260. To allow the selective targeting of the secondary dies, the primary die 205 includes a tri-state buffer 241 that couples to the multiplexer 235 and may selectively tri-state the debugging signals from the multiplexer 235. In the following discussion, it will be assumed that the debugging protocol is SWD due to its advantageous star-bus networking topology and using only two terminals for the SWDIO and SWCLK signals. Should the debugging target be the target circuit 255 in the host die 205, the debug system 250 controls the tri-state buffer 241 to isolate the SWCLK and SWDIO paths from the multiplexer 235 to corresponding inter-chiplet GPIO terminals 240 on the host die. But if the debugging is directed to a target circuit in one of the secondary dies such as a target circuit 285 in the secondary die 260, the debug subsystem controls the tri-state buffer 241 to be open or transparent so as to allow the SWCLK and the SWDIO signals to pass from the multiplexer 235 to inter-chiplet GPIO terminals 240 in the host die 205 that couple to corresponding inter-chiplet GPIO terminals 280 in the secondary die 260. The inter-chiplet GPIO terminals 240 may also couple to inter-chiplet GPIO terminals in additional secondary chiplets (not illustrated).

In the secondary die 260, the debugging signals SWCLK and SWDIO couple from the inter-chiplet GPIO terminals 280 through a tri-state buffer 281 to a multiplexer 270 and from the multiplexer 270 to a debug subsystem 275 for the debugging of the target circuit 285. It may be seen that the multiplexer 270 is analogous to the multiplexer 235. Similarly, the debug subsystem 275 is analogous to the debug subsystem 250. Should the debugging signals instead be directed to another secondary die, the debug subsystem 275 controls the tri-state buffer 281 to isolate the multiplexer 270 (and thus also the debug subsystem 275) from the debugging signals. For example, the debugging signals SWCLK and SDIO may instead couple from the inter-chiplet GPIO terminals 240 to the corresponding inter-chiplet GPIO terminals of an additional secondary die (not illustrated). A tri-state buffer within this secondary die would be arranged between the secondary die's inter-chiplet GPIO terminals and a multiplexer analogously to the arrangement of the tri-state buffer 281. The debug subsystems 250 and 275 may write to registers in their respective target circuits 255 and 285 using the advanced extensible interface (AXI) bus protocol in some implementations.

Assuming that the SWD debugging protocol is used by the system 200, the resulting inter-die networking of the debugging signals SWDIO and SWCLK between the primary chiplet 205 and the secondary chiplets advantageously occurs over the star bus network topology as discussed with regard to FIG. 1. However, a daisy-chain network topology may be used in case of a JTAG-based debugging implementation. As discussed with respect to system 100, the EUD debugger 210 may instead use a system trace debugging protocol or a UART debugging protocol for the debugging of the target circuits in alternative implementations. Regardless of what debugging protocol is used, the USB interface 220 packetizes the debugging signals from the EUD controller 230 into USB-formatted data packets that may be received by the EUD debugger 210. Similarly, the EUD debugger 210 packetizes the debugging signals into USB-formatted data packets that may couple through the USB interface 220. For example, should the SWD debugging protocol be used, the EUD controller 230 may then translate the USB-formatted data packets into the SWDIO and SWDCLK signals. More generally, the EUD controller 230 may translate the USB-formatted data packets into whatever debugging protocol is used such as to translate into JTAG signals, system trace debugging signals, or into UART debugging signals.

To maintain backwards compatibility, the multiplexer in each secondary die may also couple through GPIO terminals to its own external debugger in some implementations. For example, the multiplexer 270 in the secondary die 260 may couple through GPIO terminals 265 to an additional external debugger (not illustrated). But this additional external debugger is advantageously replaced by the EUD debugger 210 (or the JTAG-based debugger 215). Some chipset-based systems will now be discussed.

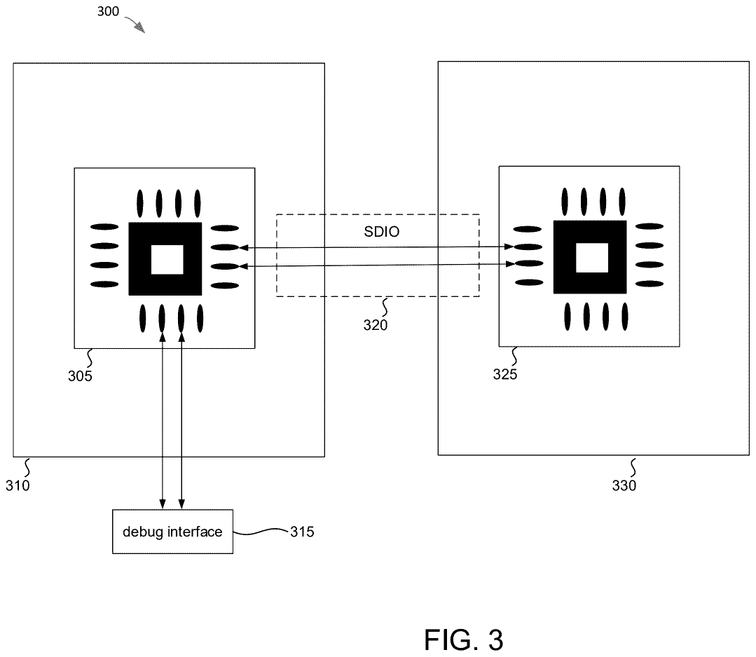

A chipset-based system 300 shown in FIG. 3 is analogous to the chiplet-based system 100 in that it includes a host die 305 and at least one secondary die 325. For illustration clarity, FIG. 3 shows only a single secondary die 325 but it will be appreciated that additional secondary dies may be included in system 300. The host die 305 is encapsulated in an integrated circuit package 310. Similarly, the secondary die 325 is encapsulated in an integrated circuit package 330. An external debugger (not illustrated) such as an EUD debugger couples through a debug interface 315 such as an EUD interface to a corresponding debug subsystem (not illustrated) in the host die 310. In system 300, the debugging protocol is SWD, but it will be appreciated that JTAG may be used in alternative implementations. Two terminals of a die-to-die interconnect for each die may be reserved to network the SWD debugging signals from the host die 310 to the secondary die 330. Similarly, a minimum of four terminals of the die-to-die interconnect may be reserved or assigned to network the JTAG debugging signals from the host die 310 to the secondary die 330. The reserved pins present in any suitable die-to-die interconnect protocol can be repurposed to implement the debugging signaling networking. In system 300, reserved terminals from a secure digital input/output (SDIO) interface 320 are used for the debugging signaling networking between the host die 305 and the secondary die 325. The resulting debugging system 300 is quite advantageous as the complexity and cost of needing a separate external debugger for the secondary die 325 is eliminated. Although a single secondary die 325 is shown, system 300 is readily adapted to debug more than one secondary die.

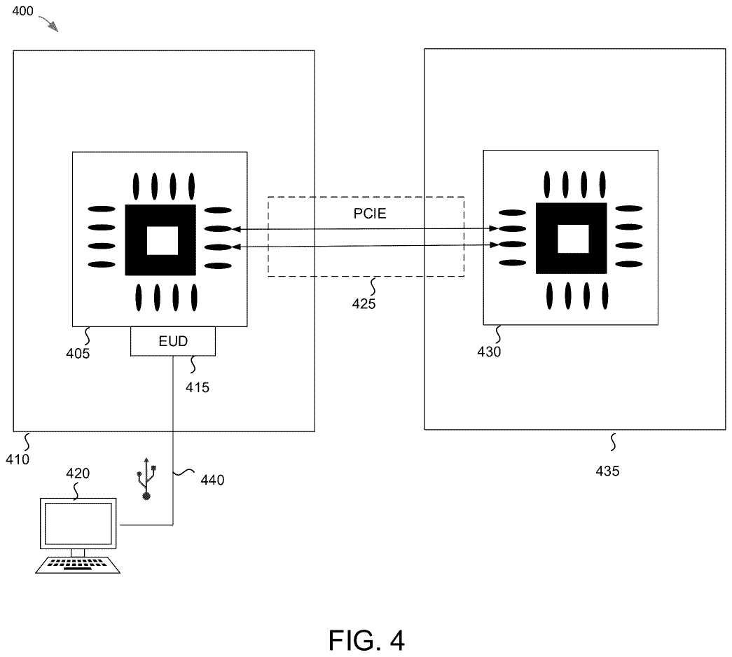

An alternative chipset-based system 400 is shown in FIG. 4 that uses reserved terminals from a peripheral component interconnect express (PCI Express) interface 425 to network the debugging signals between a host die 405 and an at least one secondary die 430. The host die 405 is encapsulated in an integrated circuit package 410. Similarly, the secondary die 430 is encapsulated in an integrated circuit package 435. An external debugger such as an EUD debugger 420 couples through a USB interface 440 to an EUD debug subsystem 415 to the host die 405. As discussed for systems 100, 200, and 300 the debugging in system 400 is quite advantageous as the complexity and cost of needing a separate external debugger for the secondary die 430 is eliminated. It will be appreciated that the reserved terminals for the die-to-die networking of SWD/JTAG debugging is not limited to PCIE or SDIO terminals. For example, each die may include a set of GPIO terminals that are reserved for the networking of the SWD/JTAG debugging signals.

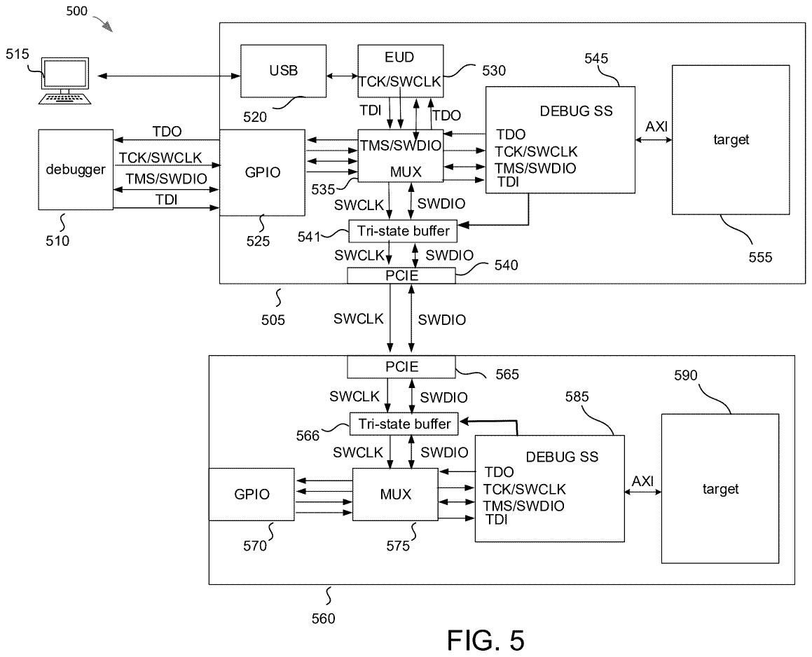

An example chipset-based system 500 is shown in more detail in FIG. 5 in which a set of reserved terminals for the die-to-die transmission of the debugging signals is a set of PCI Express (PCIE) terminals, but it will be appreciated that another die-to-die communication protocol such as SDIO may be used to implement the reserved set of terminals in alternative implementations. System 500 includes a host die 505 and one or more secondary dies (for illustration clarity, only a single secondary die 560 is shown in FIG. 5). Each die 505 and 560 is encapsulated into a corresponding integrated circuit package that are not shown for illustration clarity. An external EUD debugger 515 couples through a USB interface 520 to an EUD controller 530 in the host die 505. Should the SWD debugging protocol be used by the EUD debugger 515, the EUD controller 530 interfaces through a multiplexer 535 with the SWDIO and SWDCLK signals. Alternatively, the EUD debugger 515 may use the JTAG debugging protocol so that the EUD controller 530 interfaces through the multiplexer 535 with the JTAG TDIO, TDO, TMS, and TCK signals. If the debugging signals are directed to the debugging of the host die 505, the debugging signals couple through the multiplexer 535 to a debug subsystem 545 for the debugging of a target circuit 555 in the host die 505. The debugging system 545 would then control a tri-state buffer 541 to block the debugging signals from coupling to the secondary dies such as to the secondary die 560. If, however, the debugging signals are directed to the debugging of a secondary die, the debugging signals couple from the multiplexer 535 and through the tri-state buffer 541 to PCIE terminals 540 in the host die 505 that couple to corresponding PCIE terminals 565 in the secondary die 560. In alternative implementation, the die-to-die terminals for the debugging signals may instead be SDIO terminals. Regardless of the debugging protocol, the debugging signals may couple through the USB interface 520 and the EUD controller 530 to the multiplexer 535. From the multiplexer 535, the debugging signals either route to the debug subsystem 545 (should the debugging target circuit be the target circuit 555) or route to a secondary die such as the secondary die 125 or 130.

In the secondary die 560, the SWD/JTAG debugging signals couple from a corresponding set of reserved PCIE terminals 565 through a tri-state buffer 566 to a multiplexer 575 and from the multiplexer 575 to a debug subsystem 585 for the debugging of a target circuit 590. The debug subsystem 585 controls the tri-state buffer 566 to be transparent so as to pass the debugging signals during the debugging of the target circuit 590. Conversely, the debug subsystem 585 controls the tri-state buffer 566 to be opaque so that the debug system 585 is isolated from the debugging signals while other secondary dies or the primary die 505 are targeted for debugging. It may be seen that the multiplexer 575 is analogous to the multiplexer 535. Similarly, the debug subsystem 585 is analogous to the debug subsystem 545. Should the debugging signals instead be directed to another secondary die, the debugging signals couple from the PCIE terminals 540 in the host die 505 to the corresponding PCIE terminals of the additional secondary die. Assuming that the SWD protocol is used, the resulting inter-die networking advantageously occurs over the star bus network topology as discussed with regard to FIG. 1. However, a daisy-chain network topology may be used for a JTAG implementation. For example, the host die 505 may instead interface with a JTAG-based external debugger 510 rather than the EUD-based debugger 515. The JTAG-based debugger 510 couples through at least four GPIO terminals 525 to the multiplexer 535. From the multiplexer 535, the JTAG debugging signals would then be directed to the debug subsystem 545 should the debugging be directed to the target circuit 555. Alternatively, the JTAG signals may couple from the multiplexer 535 through the PCIE terminals 540 to a secondary die such as to the secondary die 560 for the debugging of the target circuit 590.

To maintain backwards compatibility, the multiplexer in each secondary die may also couple through GPIO terminals to an additional external debugger in some implementations. For example, the multiplexer 575 in the secondary die 560 may couple through GPIO terminals 570 to an additional external debugger (not illustrated). But this additional external debugger is advantageously replaced by the EUD-based debugger 515 (or the JTAG-based debugger 510).

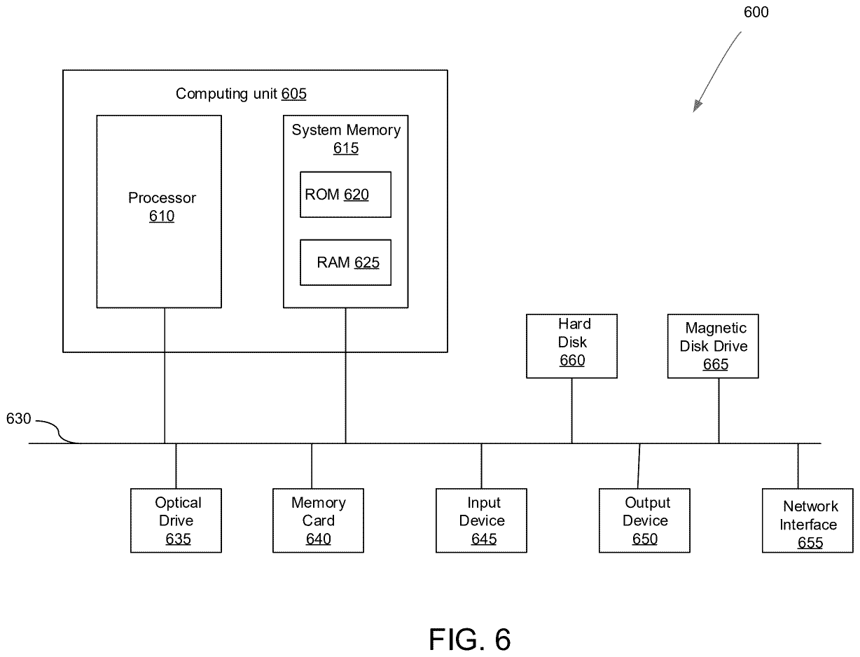

The EUD controllers 230 and 530 as well as the debug subsystems 250, 275, 545, and 585 may be implemented in any suitable computing system. An example computing system 600 is shown in FIG. 6. As seen in this figure, the computing system 600 includes a computing unit 605 with an at least one processor 610 that executes instructions from and stores data in a system memory 615. The at least one processor 610 may be any type of programmable electronic device for executing software instructions but will typically be one or more microprocessors. The system memory 615 may include both a read-only memory (ROM) 620 and a random-access memory (RAM) 625. As will be appreciated by those of ordinary skill in the art, both the read-only memory (ROM) 620 and the random-access memory (RAM) 625 may store software instructions for execution by the at least one processor 610.

The at least one processor 610 and the system memory 615 are connected, either directly or indirectly, through a bus 630 or alternate communication structure, to one or more peripheral devices. For example, the at least one processor 610 or the system memory 615 may be directly or indirectly connected to one or more additional memory storage devices, such as a “hard” magnetic disk drive 660, a removable magnetic disk drive 665, an optical disk drive 635, or a flash memory card 640. The at least one processor 610 and the system memory 615 also may be directly or indirectly connected to one or more input devices 645 and one or more output devices 650. The input devices 645 may include, for example, a keyboard, a pointing device (such as a mouse, touchpad, stylus, trackball, or joystick), a scanner, a camera, and a microphone. The output devices 645 may include, for example, a monitor display, a printer and speakers. With various examples of the computer system 600, one or more of the peripheral devices 635, 640, 645, 650, 660, and 665 may be internally housed within a housing of the computer system 600. Alternately, one or more of the peripheral devices 635, 640, 645, 650, 660, and 665 may be external to the housing and connected to the bus 630 through, for example, a Universal Serial Bus (USB) connection.

With some implementations, the computing system 600 may be directly or indirectly connected to one or more network interfaces 655 for communicating with other devices making up a network. The network interface 655 translates data and control signals from the computer system 600 into network messages according to one or more communication protocols, such as the transmission control protocol (TCP) and the Internet protocol (IP). Also, the interface 655 may employ any suitable connection agent (or combination of agents) for connecting to a network, including, for example, a wireless transceiver, a modem, or an Ethernet connection. Such network interfaces and protocols are well known in the art, and thus will not be discussed here in more detail. It should be appreciated that the computing system 600 is illustrated as an example only, and it not intended to be limiting. Various implementations may be formed using one or more computing systems that include the components of the system 600 illustrated in FIG. 6 or which include only a subset of the components illustrated in FIG. 6, or which include an alternate combination of components, including components that are not shown in FIG. 6.

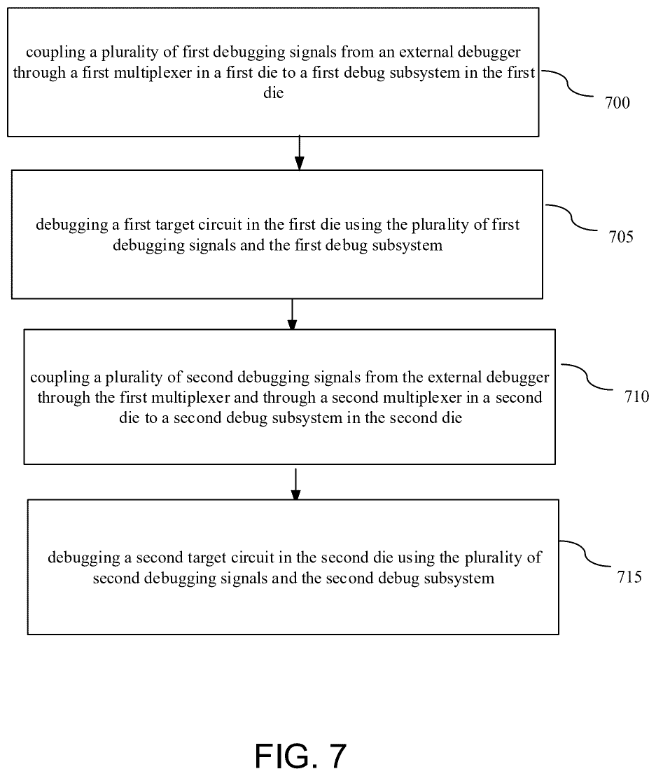

A method of debugging will now be discussed with respect to the flowchart of FIG. 7. The method includes an act 700 of coupling a plurality of first debugging signals from an external debugger through a first multiplexer in a first die to a first debug subsystem in the first die. The coupling of debugging signals for the debugging of the target circuit 255 through the first multiplexer 235 and also the coupling of the debugging signals through the multiplexer 535 for the debugging of the target circuit 555 are examples of act 700. The method also includes an act 705 of debugging a first target circuit in the first die using the plurality of first debugging signals and the first debug subsystem. The debugging of the target circuit 255 by the debug subsystem 250 and also the debugging of the target circuit 555 by the debug subsystem 545 are examples of act 705. In addition, the method includes an act 710 of coupling a plurality of second debugging signals from the external debugger through the first multiplexer and through a second multiplexer in a second die to a second debug subsystem in the second die. The coupling of debug signals for the debugging of the target circuit 255 from the first multiplexer 235 through the second multiplexer 270 to the debug subsystem 275 is an example of act 715. Similarly, the coupling of debug signals for the debugging of the target circuit 590 from the first multiplexer 353 through the second multiplexer 575 to the debug subsystem 585 is an example of act 715. Finally, the method includes an act 720 of debugging a second target circuit in the second die using the plurality of second debugging signals and the second debug subsystem. The debugging of the target circuits 285 and 590 are examples of act 720.

Some example implementations will now be summarized through the following numbered clauses:

Clause 1. A system, comprising:
a first chiplet die including:
   a first debugging interface for coupling to an external debugger;
   a first multiplexer coupled to the first debugging interface;
   a first target circuit;
   a first debug subsystem configured to debug the first target circuit with first debugging signals coupled through the first multiplexer from the first debugging interface;
   a first set of terminals from a first inter-chiplet interface, wherein the first set of terminals is coupled to the first multiplexer; and
a second chiplet die including:
   a second set of terminals from a second inter-chiplet interface, wherein the second set of terminals is coupled to the first set of terminals;
   a second multiplexer coupled to the second set of terminals;
   a second target circuit; and
   a second debug subsystem configured to debug the second target circuit with second debugging signals coupled through the second multiplexer from the second set of terminals.

Clause 2. The system of clause 1 wherein the first inter-chiplet interface and the second inter-chiplet interface each comprises an inter-chiplet general purpose input/output (GPIO) interface.

Clause 3. The system of any of clauses 1-2, further comprising:
a first tri-state buffer coupled between the first multiplexer and the first inter-chiplet interface, wherein the first debug subsystem is further configured to control the first tri-state buffer to block the first debugging signals and to pass the second debugging signals.

Clause 4. The system of clause 3, further comprising:
a second tri-state buffer coupled between the second multiplexer and the second inter-chiplet interface, wherein the second debug subsystem is further configured to control the second tri-state buffer to pass the second debugging signals and to block the first debugging signals.

Clause 5. The system of any of clauses 1-4, wherein the first chiplet die further includes:
a JTAG debugging interface configured to couple to an external JTAG debugger, wherein the first multiplexer is further coupled to the JTAG debugging interface.

Clause 6. The system of any of clauses 1-5, further comprising:
a star bus network; and
a third chiplet die including:
   a third set of terminals from a third inter-chiplet interface, wherein the third set of terminals is coupled to the first set of terminals through the star bus network, and wherein the second set of terminals is also coupled to the first set of terminals through the star bus network.

Clause 7. The system of clause 6, wherein the first debugging signals and the second debugging signals comprise serial wire debug signals.

Clause 8. The system of any of clauses 1-5, further comprising:
a daisy-chain network; and
a third chiplet die including:
   a third set of terminals from a third inter-chiplet interface, wherein the third set of terminals is coupled to the first set of terminals through the daisy-chain network, and wherein the second set of terminals is also coupled to the first set of terminals through the daisy-chain network.

Clause 9. The system of clause 8, wherein the first debugging signals and the second debugging signals comprise JTAG signals.

Clause 10. A method of debugging, comprising:
coupling a plurality of first debugging signals from an external debugger through a first multiplexer in a first die to a first debug subsystem in the first die;
debugging a first target circuit in the first die using the plurality of first debugging signals and the first debug subsystem;
coupling a plurality of second debugging signals from the external debugger through the first multiplexer and through a second multiplexer in a second die to a second debug subsystem in the second die; and
debugging a second target circuit in the second die using the plurality of second debugging signals and the second debug subsystem.

Clause 11. The method of clause 10, further comprising:
coupling the plurality of second debugging signals from the first multiplexer through a first plurality of peripheral component interconnect express terminals for the first die to a second plurality of peripheral component interconnect express terminals for the second die.

Clause 12. The method of clause 11, further comprising:
isolating the first plurality of peripheral component interconnect express terminals for the first die from the plurality of first debugging signals.

### Clause 13. the Method of Clause 10, Further Comprising:

coupling the plurality of second debugging signals from the first multiplexer through a first plurality of secure digital input output terminals for the first die to a second plurality of secure digital input output terminals for the second die.

Clause 14. The method of clause 13, further comprising:
isolating the second debug subsystem from the second plurality of secure digital input output terminals while the external debugger debugs a third target circuit in a third die through the first multiplexer.

Clause 15. The method of clause 10, further comprising:
coupling the plurality of second debugging signals from the first multiplexer through a first plurality of GPIO terminals for the first die to a second plurality of GPIO terminals for the second die.

Clause 16. A system, comprising:
a first chipset die including:
   a first debugging interface for coupling to an external debugger;
   a first multiplexer coupled to the first debugging interface;
   a first target circuit;
   a first debug subsystem configured to debug the first target circuit with first debugging signals coupled through the first multiplexer from the first debugging interface;
   a first set of terminals from a first die-to-die interface, wherein the first set of terminals is coupled to the first multiplexer; and
a second chiplet die including:
   a second set of terminals from a second die-to-die interface, wherein the second set of terminals is coupled to the first set of terminals;
   a second multiplexer coupled to the second set of terminals;
   a second target circuit; and
   a second debug subsystem configured to debug the second target circuit with second debugging signals coupled through the second multiplexer from the second set of terminals.

Clause 17. The system of clause 16, wherein the first die-to-die interface and the second die-to-die interface each comprises a set of reserved terminals from a peripheral component express interface.

Clause 18. The system of clause 16, wherein the first die-to-die interface and the second die-to-die interface each comprises a set of reserved terminals from a secure digital input output interface.

Clause 19. The system of clause 16, wherein the first debug subsystem and the second debug subsystem each comprises a serial wire debug subsystem.

Clause 20. The system of clause 16, wherein the first debug subsystem and the second debug subsystem each comprises a JTAG debug subsystem.

Clause 21. The system of clause 16, wherein the first die-to-die interface and the second die-to-die interface each comprises a set of reserved terminals from a general purpose input/output (GPIO) interface.

As those of some skill in this art will by now appreciate and depending on the particular application at hand, many modifications, substitutions and variations can be made in and to the materials, apparatus, configurations and methods of use of the devices of the present disclosure without departing from the scope thereof as defined by the appended claims. In light of this, the scope of the present disclosure should not be limited to that of the particular implementations illustrated and described herein, as they are merely by way of some examples thereof, but rather, should be fully commensurate with that of the claims appended hereafter and their functional equivalents.

What is claimed is:

1. A system, comprising:
a first chiplet die including:
a first debugging interface for coupling to an external debugger;
a first multiplexer coupled to the first debugging interface;
a first target circuit;
a first debug subsystem configured to debug the first target circuit with first debugging signals coupled through the first multiplexer from the first debugging interface;
a first set of terminals from a first inter-chiplet interface, wherein the first set of terminals is coupled to the first multiplexer; and
a second chiplet die including:
a second set of terminals from a second inter-chiplet interface, wherein the second set of terminals is coupled to the first set of terminals;
a second multiplexer coupled to the second set of terminals;
a second target circuit; and
a second debug subsystem configured to debug the second target circuit with second debugging signals coupled through the second multiplexer from the second set of terminals.

2. The system of claim 1, wherein the first inter-chiplet interface and the second inter-chiplet interface each comprises an inter-chiplet general purpose input/output (GPIO) interface.

3. The system of claim 1, further comprising:
a first tri-state buffer coupled between the first multiplexer and the first inter-chiplet interface, wherein the first debug subsystem is further configured to control the first tri-state buffer to block the first debugging signals and to pass the second debugging signals.

4. The system of claim 3, further comprising:
a second tri-state buffer coupled between the second multiplexer and the second inter-chiplet interface, wherein the second debug subsystem is further configured to control the second tri-state buffer to pass the second debugging signals and to block the first debugging signals.

5. The system of claim 1, wherein the first chiplet die further includes:
a JTAG debugging interface configured to couple to an external JTAG debugger, wherein the first multiplexer is further coupled to the JTAG debugging interface.

6. The system of claim 1, further comprising:
a star bus network; and
a third chiplet die including:
a third set of terminals from a third inter-chiplet interface, wherein the third set of terminals is coupled to the first set of terminals through the star bus network, and wherein the second set of terminals is also coupled to the first set of terminals through the star bus network.

7. The system of claim 6, wherein the first debugging signals and the second debugging signals comprise serial wire debug signals.

8. The system of claim 1, further comprising:
a daisy-chain network; and
a third chiplet die including:
a third set of terminals from a third inter-chiplet interface, wherein the third set of terminals is coupled to the first set of terminals through the daisy-chain network, and wherein the second set of terminals is also coupled to the first set of terminals through the daisy-chain network.

9. The system of claim 8, wherein the first debugging signals and the second debugging signals comprise JTAG signals.

10. A method of debugging, comprising:
coupling a plurality of first debugging signals from an external debugger through a first multiplexer in a first die to a first debug subsystem in the first die;
debugging a first target circuit in the first die using the plurality of first debugging signals and the first debug subsystem;
coupling a plurality of second debugging signals from the external debugger through the first multiplexer and through a second multiplexer in a second die to a second debug subsystem in the second die; and
debugging a second target circuit in the second die using the plurality of second debugging signals and the second debug subsystem.

11. The method of claim 10, further comprising:
coupling the plurality of second debugging signals from the first multiplexer through a first plurality of peripheral component interconnect express terminals for the first die to a second plurality of peripheral component interconnect express terminals for the second die.

12. The method of claim 11, further comprising:
isolating the first plurality of peripheral component interconnect express terminals for the first die from the plurality of first debugging signals.

13. The method of claim 10, further comprising:
coupling the plurality of second debugging signals from the first multiplexer through a first plurality of secure digital input output terminals for the first die to a second plurality of secure digital input output terminals for the second die.

14. The method of claim 13, further comprising:
isolating the second debug subsystem from the second plurality of secure digital input output terminals while the external debugger debugs a third target circuit in a third die through the first multiplexer.

15. The method of claim 10, further comprising:
coupling the plurality of second debugging signals from the first multiplexer through a first plurality of GPIO terminals for the first die to a second plurality of GPIO terminals for the second die.

16. A system, comprising:
a first chipset die including:
a first debugging interface for coupling to an external debugger;
a first multiplexer coupled to the first debugging interface;
a first target circuit;
a first debug subsystem configured to debug the first target circuit with first debugging signals coupled through the first multiplexer from the first debugging interface;
a first set of terminals from a first die-to-die interface, wherein the first set of terminals is coupled to the first multiplexer; and
a second chiplet die including:
a second set of terminals from a second die-to-die interface, wherein the second set of terminals is coupled to the first set of terminals;
a second multiplexer coupled to the second set of terminals;
a second target circuit; and
a second debug subsystem configured to debug the second target circuit with second debugging signals coupled through the second multiplexer from the second set of terminals.

17. The system of claim 16, wherein the first die-to-die interface and the second die-to-die interface each comprises a set of reserved terminals from a peripheral component express interface.

18. The system of claim 16, wherein the first die-to-die interface and the second die-to-die interface each comprises a set of reserved terminals from a secure digital input output interface.

19. The system of claim 16, wherein the first debug subsystem and the second debug subsystem each comprises a serial wire debug subsystem.

20. The system of claim 16, wherein the first debug subsystem and the second debug subsystem each comprises a JTAG debug subsystem.

21. The system of claim 16, wherein the first die-to-die interface and the second die-to-die interface each comprises a set of reserved terminals from a general purpose input/output (GPIO) interface.
